(19) United States
(12) Patent Application Publication
(10) Pub. No.: US 2024/0036415 A1
(43) Pub. Date: Feb. 1, 2024

(54) ARRAY SUBSTRATE AND DISPLAY DEVICE

(71) Applicant: TCL CHINA STAR OPTOELECTRONICS TECHNOLOGY CO., LTD., Shenzhen, Guangdong (CN)

(72) Inventor: Hanxian Liu, Shenzhen, Guangdong (CN)

(73) Assignee: TCL CHINA STAR OPTOELECTRONICS TECHNOLOGY CO., LTD., Shenzhen, Guangdong (CN)

(21) Appl. No.: 17/622,773

(22) PCT Filed: Dec. 17, 2021
(86) PCT No.: PCT/CN2021/139291

§ 371 Date: Dec. 24, 2021

(30) Foreign Application Priority Data
Dec. 10, 2021 (CN) 202111509916.6

(51) Int. Cl. G02F 1/1362; H10K 59/131; H10K 59/38

(52) U.S. Cl. CPC G02F 1/136286; G02F 1/136222; H10K 59/131; H10K 59/38

(57) ABSTRACT

A display device and an array substrate including a flexible circuit substrate, first and second pad groups, a source-driving chip, and a gate-driving chip are disclosed. The flexible circuit substrate includes a substrate, first and second film layers. Outputs of the gate-driving chip are connected with the second film layer wirings through the first film layer wirings and the third via holes, and the second film layer wirings are connected with the first pad group through the first via holes and the first film layer wirings. First outputs of the source-driving chip are connected with the second pad group through the first film layer wirings in a bending area. By arranging the gate-driving chip and the source-driving chip on the flexible circuit substrate together, the sides of array substrate are unnecessary to be provided with gate-driving circuits or bonding areas therefor, thereby reducing the bezel of display device.

### FIELD OF INVENTION

The present disclosure relates to the field of display technology, and more particularly, to an array substrate and a display device.

### BACKGROUND OF INVENTION

As consumer electronics tends to be light and thin and has narrow bezel, high resolutions, and large screen-to-body ratios, there is the requirement for the size of bottom bezel of the display module to be smaller and smaller. Chip on glass (COG) is a widely technology used in the existing display module, but this kind of direct bonding of integrated circuit chip (IC) onto the display panel glass may occupy the non-display area of the screen on the display panel, which is disadvantageous to the realization of ultra-narrow bezel or full screen of the display panel.

At present, in order to achieve the design of ultra-narrow bezel, the packaging technology of chip on film (COF) is generally used to arrange the driving chip (e.g., source-driving chip) required by the display panel on the flexible circuit board that is connected with the display panel, so as to reduce the area of the array substrate for arranging the driving chip. However, for the display panel with gate driver on array (GOA), although the costs of the gate-driving chip can be saved by arranging the gate-driving circuits on two sides of the array substrate, the design of ultra-narrow bezel is also limited to the gate-driving circuits on two sides of the display panel, which fails to meet the requirement further for bezel-less. Therefore, it is necessary to provide a new chip on film technology to achieve bezel-less design.

### SUMMARY OF INVENTION

### Technical Problem

An array substrate with new chip on film structure is disclosed in the present disclosure to solve the problem that the bezel of the display panel cannot be further reduced.

### Technical Solutions

In order to solve the aforementioned problem, one aspect of the present disclosure is to provide an array substrate including a first substrate, a flexible circuit substrate, a first film layer, a second film layer, a source-driving chip, and a gate-driving chip. The flexible circuit substrate is connected with the first substrate, and has a first area close to the first substrate, a second area located on one side of the first area away from the first substrate, and a third area located on one side of the second area away from the first area. The flexible circuit substrate includes a second substrate, a first film layer, and a second film layer. The first film layer is disposed on the second substrate and forms a plurality of wirings. The second film layer is disposed under the second substrate and forms a plurality of wirings. A plurality of first via holes in the first area and a plurality of third via holes in the third area are formed between the first film layer and the second film layer. The first pad group is disposed on the first film layer and located in the second area. The second pad group is disposed on the first film layer and located in the second area, and located on one side of the first pad group away from the first substrate. The source-driving chip is disposed on the first film layer and located in the third area, wherein a first output end of the source-driving chip is connected with a pad in the second pad group through the wiring of the first film layer. The gate-driving chip is disposed on the first film layer and located in the third area, and located on one side of the source-driving chip away from the second pad group. An output end of the gate-driving chip is connected with the wiring of the second film layer through the wiring of the first film layer and the third via hole, and the wiring of the second film layer is connected with a pad of the first pad group through the first via hole and the wiring of the first film layer.

In some embodiments, the flexible circuit substrate further has a fourth area located between the second area and the third area, and a plurality of fourth via holes in the fourth area are further formed between the first film layer and the second film layer. A second output end of the source-driving chip is connected with the wiring of the second film layer through the wiring of the first film layer and the fourth via hole, and the wiring of the second film layer is connected with a pad of the first pad group through the first via hole and the wiring of the first film layer.

In some embodiments, the first film layer forms a plurality of first upper wirings, a plurality of third upper wirings, and a plurality of fourth upper wirings in the first area, the third area, and the fourth area, respectively. The output end of the gate-driving chip is connected with the wiring of the second film layer through third upper wiring and the third via hole, and the wiring of the second film layer is connected with the pad of the first pad group through the first via hole and the first upper wiring.

In some embodiments, the first output end of the source-driving chip is directly connected with the pad of the second pad group through the fourth upper wiring.

In some embodiments, the second output end of the source-driving chip is connected with the wiring of the second film layer through the fourth upper wiring and the fourth via hole, and the wiring of the second film layer is connected with the pad of the first pad group through the first via hole and the first upper wiring.

In some embodiments, the number of the first output ends is greater than the number of the second output ends.

In some embodiments, a plurality of pads of the first pad group and a plurality of pads of the second pad group are aligned with each other.

In some embodiments, a plurality of pads of the first pad group and a plurality of pads of the second pad group are staggered with each other.

In some embodiments, the wiring of the first film layer in the first area is further led out to connect with a test pad.

Another aspect of the present disclosure is to provide a display device including an array substrate described in any one of the aforementioned embodiments and a third substrate. The third substrate is disposed opposite the array substrate.

### Beneficial Effect

In the array substrate and the display device disclosed in the embodiments of the present disclosure, the gate-driving chip and the source-driving chip are arranged on the flexible circuit substrate together, so that it is unnecessary to provide a gate-driving circuit or a bonding area of a gate-driving chip on the sides of the array substrate of the display device, thereby further reducing the bezel of the display device. Moreover, the gate-driving chip is connected to the first pad group through the third via hole in the third area, the wiring of the second film layer, and the first via hole in the first area, rather than the fourth via hole in the bending area (i.e., the fourth area), so that the number of via holes in the bending area is greatly reduced and poor bending of the flexible circuit substrate is avoided. Furthermore, most of the wirings connected with the source-driving chip and the wirings connected with the gate-driving chip are staggered, so as to avoid short circuit of the wirings in the bonding area (i.e., the second area). The line spacing between the wirings of the first film layer and the wirings of the second film layer can be further reduced, so as to reduce the area required by the flexible circuit substrate and simplify the complexity of circuit layout design.

### DESCRIPTION OF DRAWINGS

The technical solutions and other beneficial effects of the present disclosure are obvious by describing the specific embodiments of the present disclosure in combination with the accompanying drawings in detail.

FIG. 1 illustrates a schematic diagram of an array substrate according to some embodiments of the present disclosure.

FIG. 2 illustrates a cross-sectional side view of the flexible circuit substrate in FIG. 1 taken along the line LL.

FIG. 3 illustrates a schematic diagram of an arrangement of pads according to an embodiment of the present disclosure.

FIG. 4 illustrates a schematic diagram of an arrangement of driving chips according to an embodiment of the present disclosure.

### DETAILED DESCRIPTION OF PREFERRED EMBODIMENTS

The technical solutions in the embodiments of the present disclosure are clearly and completely described below in combination with the accompanying drawings in the embodiments of the present disclosure. Obviously, the described embodiments are only a part of the embodiments of the present disclosure rather than all of the embodiments. Based on the embodiments in the present disclosure, all other embodiments obtained by a person of ordinary skill in the art without creative efforts fall within the claim scope of the present disclosure.

The description of each embodiment below refers to respective accompanying drawing(s), so as to illustrate exemplarily specific embodiments of the present disclosure that may be practiced. Directional terms mentioned in the present disclosure, such as “upper”, “lower”, “front”, “back”, “left”, “right”, “top”, “bottom”, “inner”, “outer”, etc., are only directions by referring to the accompanying drawings, and thus the directional terms are used to describe and understand the present disclosure, but the present disclosure is not limited thereto. In the drawings, structurally similar units are labeled by the same reference numerals. In the drawings, for understanding and ease of description, the thickness of some layers and areas is exaggerated. That is, the size and thickness of each component shown in the drawings are arbitrarily shown, but the present disclosure is not limited thereto.

It should be noted that, in descriptions of the present disclosure, terms such as “first” and “second” are used herein for purposes of description and are not intended to indicate or imply relative importance or significance. In addition, in the description of the present disclosure, “a plurality of” relates to two or more than two, unless specified or limited otherwise.

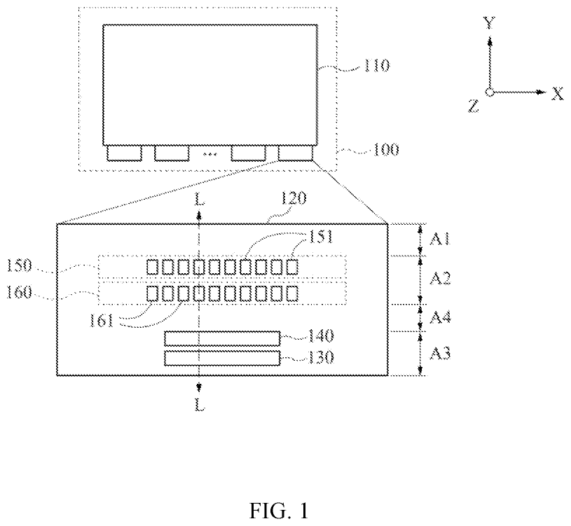

FIG. 1 illustrates a schematic diagram of an array substrate 100 according to some embodiments of the present disclosure. The array substrate 100 may be included in a display device, and be disposed opposite a third substrate (not shown in the figure) of the display device. In some embodiments, if the display device is a liquid crystal display device, the third substrate may be a color filter substrate, wherein a liquid crystal layer may be provided between the third substrate and the array substrate 100. In some embodiments, if the display device is an organic light-emitting diode (OLED) display device, the third substrate may be a protective substrate, wherein an organic light-emitting layer may be provided between the third substrate and the array substrate 100.

The array substrate 100 may include a first substrate 110 and a plurality of flexible circuit substrates 120. A pixel array including switching transistors may be formed on the first substrate 110. In one embodiment, the first substrate 110 may be made of a rigid substrate (e.g., glass). In another embodiment, the first substrate 110 may be made of a flexible substrate (e.g., polyimide), and the present disclosure is not limited thereto. The flexible circuit substrate 120 may be bonded to the first substrate 110 with a chip on film (COF) structure, and may be bent to the back of the first substrate 110 (i.e., the display device). The flexible circuit substrate 120 is provided with a first pad group 150 including a plurality of pads 151 and a second pad group 160 including a plurality of pads 161. In the present embodiment, the gate-driving chip 130 and the source-driving chip 140 are disposed on the flexible circuit substrate 120 together. The gate-driving chip 130 is connected with the pad of the first pad group 150 through the wiring on the flexible circuit substrate 120 to further connect with the gate terminal of the switching transistor of each pixel in a pixel group (not shown in the figure), which is corresponding to each of the flexible circuit substrates 120, on the first substrate 110 of the array substrate 100, so as to provide a gate-driving signal to the corresponding switching transistor. The source-driving chip 140 is connected with the pads of the first pad group 150 and the second pad group 160 through the wirings on the flexible circuit substrate 120 to further connected with the source terminal of the switching transistor of each pixel in the pixel group (not shown in the figure), which is corresponding to each of the flexible circuit substrates 120, on the first substrate 110 of the array substrate 100, so as to provide an image data signal to the corresponding switching transistor.

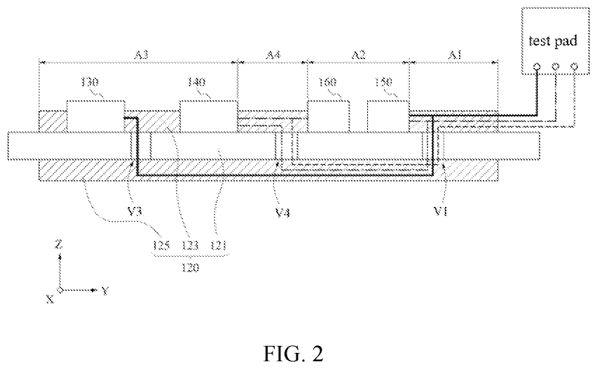

Reference is also made to FIG. 2. FIG. 2 illustrates a cross-sectional side view of the flexible circuit substrate 120 in FIG. 1 taken along the line LL. The flexible circuit substrate 120 has a first area A1, a second area A2, a third area A3, and a fourth area A4 which are connected. The second area A2 is located on the side of the first area A1 away from the display panel 130, the third area A3 is located on the side of the second area A2 away from the first area A1, and the fourth area A4 is located between the second area A2 and the third area A3. The flexible circuit substrate 120 includes a second substrate 121, a first film layer 123 disposed on the second substrate 121, and a second film layer 125 disposed under the second substrate 121. The materials of the second substrate 121, the first film layer 123, and the second film layer 125 may be polyimide.

In one embodiment, the first film layer 123 may form first upper wirings in the first area A1, second upper wirings in the second area A2, third upper wirings in the third area A3, and fourth upper wirings in the fourth area A4. The second film layer 123 may form first lower wirings in the first area A1, second lower wirings in the second area A2, third lower wirings in the third area A3, and fourth lower wirings in the fourth area A4.

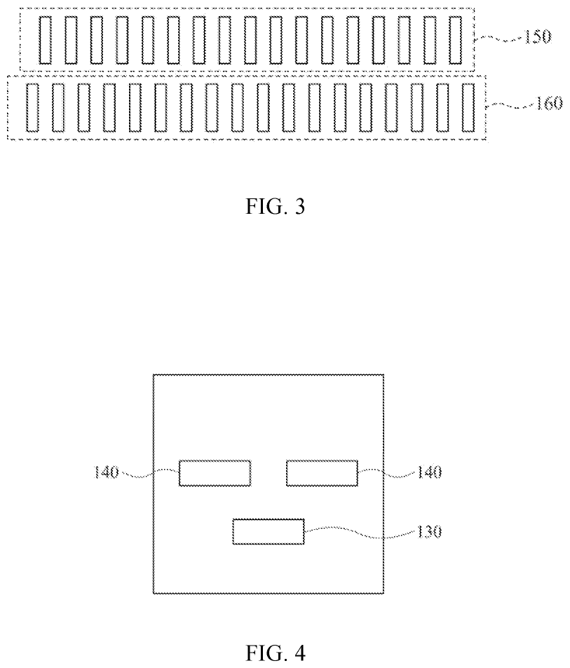

In the present embodiment, the flexible circuit substrate 120 is a double-layered (i.e., the first film layer 123 and the second film layer 125) COF substrate with a design of dual-row pads (i.e., the first pad group 150 and the second pad group 160). The first pad group 150 and the second pad group 160 are located in the second area A2 (also known as the bonding area) and are disposed on the first film layer 123. The first pad group 150 is located in the second pad group 160 close to the first substrate 110 (i.e., near the first area A1). In the embodiment of FIG. 1, the plurality of pads 151 of the first pad group 150 and the plurality of pads 161 of the second pad group 160 are aligned along the X axis, so as to facilitate the alignment bonding between the pads 151 and 161, thereby improving the yield rate. However, in such a design, the wirings connected with the pad 151 and pad 161 must be bent to avoid short circuit, and thus the design of circuit layout is more complex. In another embodiment, as shown in FIG. 3, the plurality of pads 151 of the first pad group 150 and the plurality of pads 161 of the second pad group 160 are staggered along the X axis, so that the wirings connected with the pad 151 and pad 161 can be led out directly without bending, thereby simplifying the design of the circuit layout. In contrast, the alignment bonding between the pads 151 and pads 161 is less precise. In the present disclosure, one of the above designs may be selected for the dual-row pads according to the actual situation, and the present disclosure is not limited thereto.

The gate-driving chip 130 and the source-driving chip 140 are located in the third area A3 and disposed on the first film layer 123, wherein the gate-driving chip 130 is located on the side of the source-driving chip 140 away from the first pad group 150. In other words, in the Y axis direction, the source-driving chip 140 is closer to the second pad group 160 than the gate-driving chip 130. In the embodiment of FIG. 1, the flexible circuit substrate 120 is provided with one gate-driving chip 130 and one source-driving chip 140. In another embodiment, as shown in FIG. 4, the flexible circuit substrate 120 may be provided with one gate-driving chip 130 and two source-driving chips 140. Both source-driving chips 140 are closer to the second pad group 160 than the gate-driving chip 130, but the present disclosure is not limited thereto.

In the present embodiment, in the third area A3, a plurality of third via holes V3 are formed between the first film layer 123 and the second film layer 125. In the first area A1, a plurality of first via holes V1 are formed between the first film layer 123 and the second film layer 125. In the fourth area A4, a plurality of fourth via holes V4 are formed between the first film layer 123 and the second film layer 125.

In one embodiment, a plurality of output ends (e.g., gate-driving signal output ends) of the gate-driving chip 130 can use the corresponding number of the wirings of first film layers 123 in the third area A3 (i.e., the third upper wiring) to pass through the corresponding number of the third via holes V3 to connect with the wirings of the second film layer 125 (i.e., the third lower wirings). The third lower wirings are also connected with the corresponding number of the wirings of the first film layers 123 in the first area A1 (i.e., the first upper wirings) though the second lower wirings, the first lower wirings, and the first via holes, so as to connect with the corresponding number of the pads 151 of the first pad group 150 through the first upper wirings.

In one embodiment, a plurality of first output ends (e.g., data signal output ends) of the source-driving chip 140 may be directly connected with the corresponding number of the pads 161 of the second pad group 160 through the corresponding number of the wirings of first film layers 123 in the fourth area A4 (i.e., the fourth upper wirings). Moreover, a plurality of second output ends (e.g., data signal output ends) of the source-driving chip 140 can use the corresponding number of the wirings of first film layers 123 in the fourth area A4 (i.e., the fourth upper wirings) to pass through the fourth via holes V4 to connect with the corresponding number of the wirings of the second film layer 125 (i.e., the fourth lower wirings). The fourth lower wirings are also connected with the corresponding number of the first upper wirings though the corresponding second lower wirings, the corresponding first lower wirings, and the corresponding first via holes, so as to connect with the corresponding number of the pads 151 of the first pad group 150 through the first upper wirings.

Specifically, in the present disclosure, since both the gate-driving chip 130 for providing the gate-driving signal and the source-driving chip 140 are disposed on the flexible circuit substrate 120, the side bezels of the array substrate 100 are unnecessary to arrange a gate-driving circuit or a bonding area of the gate-driving chip. As a result, the bezel of the display device can be further minimized, thereby achieving ultra-narrow bezel or even no bezel. Moreover, since the gate-driving chip 130 is farther from the pad groups than the source-driving chip 140, all pads used to connect with the output ends of the gate-driving chip 130 are located in the first pad group 150 close to the first substrate 110. Furthermore, the gate-driving chip 130 uses the third via holes V3 in the third area A3 instead of the fourth via holes V4 in the fourth area A4 (also known as the bending area) to connect with the wirings of the second film layer 125, and is connected with the pads 151 of the first pad group 150 through the wirings of the second film layer 125 and the first via holes. Therefore, the number of the via holes in the bending area can be greatly reduced (only a small part of the output ends of the source-driving chip 140 (i.e., the second output ends) are connected with the wirings of the second film layer 125 through the fourth via holes V4), so as to avoid poor bending of the flexible circuit substrate 120.

In some embodiments, the number of the first output ends is greater than the number of the second output ends. Since most of the output ends (i.e., the first output ends) of the source-driving chip 140 are directly connected to the pads 161 of the second pad group 160 through the wirings of the first film layer 123 (i.e., the fourth upper wirings), so that they and the wirings for connecting with the gate-driving chip 130 and a small part of the output ends of the source-driving chip 140 (i.e., the second output ends) are staggered, so as to avoid short circuit of the wirings in the second area A2 (i.e., the bonding area). In this way, the line spacing between the wirings of the first film layer 123 and the wirings of the second film layer 125 can be further reduced, so as to reduce the area required by the flexible circuit substrate 120 and simplify the complexity of circuit layout design.

In one embodiment, in the first area A1, the first upper wirings for connecting with the gate-driving chip 130 and the pads 151 of the first pad group 150 may also be led out and connected to, for example, a test pad. The test pad can be used for the yield test of chip on film (COF). Similarly, in the first area A1, the first upper wirings for connecting with the second output ends of the source-driving chip 140 and the pads 151 of the first pad group 150 can be further led out and similarly connected with the test pads for the yield test of COF.

In one embodiment, in the fourth area A4, the fourth upper wirings for connecting with the first output ends of the source-driving chip 140 can further be connected with the fourth lower wirings through the fourth via holes V4, and the fourth lower wirings are connected with the corresponding first upper wirings in the first area through the second lower wirings, the first lower wirings, and the first via holes. Said first upper wirings may be further led out to connect with the test pads for the yield test of COF.

To sum up, in the array substrate with COF packaging structure and the display device disclosed in the embodiments of the present disclosure, the gate-driving chip 130 and the source-driving chip 140 are arranged on the double-layered flexible circuit substrate 120 with dual-row pads together, so that it is unnecessary to provide a gate-driving circuit or a bonding area of the gate-driving chip on the sides of the array substrate 100 of the display device, thereby further reducing the bezel of the display device. Moreover, the gate-driving chip 130 is connected to the first pad group 150 through the third via hole V3 in the third area A3, the wiring of the second film layer 125, and the first via hole V1 in the first area A1, rather than the fourth via hole V4 in the bending area (i.e., the fourth area A1), so that the number of via holes in the bending area is greatly reduced and poor bending of the flexible circuit substrate is avoided. Furthermore, most of the wirings connected with the source-driving chip 140 and the wirings connected with the gate-driving chip 130 are staggered, so as to avoid short circuit of the wirings in the bonding area (i.e., the second area A2). The line spacing between the wirings of the first film layer 123 and the wirings of the second film layer 125 can be further reduced, so as to reduce the area required by the flexible circuit substrate 120 and simplify the complexity of circuit layout design.

The technical features in the aforementioned embodiments may be randomly combined. For concise description, not all possible combinations of the technical features in the embodiment are described. However, the combinations of the technical features should all be considered as falling within the scope described in this specification provided that they do not conflict with each other.

The aforementioned embodiments only show several implementations of this application and are described in detail, but they should not be construed as a limit to the patent scope of this application. It should be noted that, a person of ordinary skill in the art may make various changes and improvements without departing from the ideas of this application, which shall all fall within the protection scope of this application. Therefore, the protection scope of the patent of this application shall be subject to the appended claims.

What is claimed is:

1. An array substrate, comprising:
a first substrate;
a flexible circuit substrate connected with the first substrate, and having a first area close to the first substrate, a second area located on one side of the first area away from the first substrate, and a third area located on one side of the second area away from the first area, wherein the flexible circuit substrate comprises:
a second substrate;
a first film layer disposed on the second substrate and forming a plurality of wirings; and
a second film layer disposed under the second substrate and forming a plurality of wirings, wherein a plurality of first via holes in the first area and a plurality of third via holes in the third area are formed between the first film layer and the second film layer;
a first pad group disposed on the first film layer and located in the second area;
a second pad group disposed on the first film layer and located in the second area, and located on one side of the first pad group away from the first substrate;
a source-driving chip disposed on the first film layer and located in the third area, wherein a first output end of the source-driving chip is connected with a pad in the second pad group through the wiring of the first film layer; and
a gate-driving chip disposed on the first film layer and located in the third area, and located on one side of the source-driving chip away from the second pad group, wherein an output end of the gate-driving chip is connected with the wiring of the second film layer through the wiring of the first film layer and the third via hole, and the wiring of the second film layer is connected with a pad of the first pad group through the first via hole and the wiring of the first film layer.

2. The array substrate according to claim 1, wherein the flexible circuit substrate further has a fourth area located between the second area and the third area, and a plurality of fourth via holes in the fourth area are further formed between the first film layer and the second film layer, wherein a second output end of the source-driving chip is connected with the wiring of the second film layer through the wiring of the first film layer and the fourth via hole, and the wiring of the second film layer is connected with a pad of the first pad group through the first via hole and the wiring of the first film layer.

3. The array substrate according to claim 2, wherein the first film layer forms a plurality of first upper wirings, a plurality of third upper wirings, and a plurality of fourth upper wirings in the first area, the third area, and the fourth area, respectively, wherein the output end of the gate-driving chip is connected with the wiring of the second film layer through third upper wiring and the third via hole, and the wiring of the second film layer is connected with the pad of the first pad group through the first via hole and the first upper wiring.

4. The array substrate according to claim 3, wherein the first output end of the source-driving chip is directly connected with the pad of the second pad group through the fourth upper wiring.

5. The array substrate according to claim 3, wherein the second output end of the source-driving chip is connected with the wiring of the second film layer through the fourth upper wiring and the fourth via hole, and the wiring of the second film layer is connected with the pad of the first pad group through the first via hole and the first upper wiring.

6. The array substrate according to claim 2, wherein a number of the first output ends is greater than a number of the second output ends.

7. The array substrate according to claim 1, wherein a plurality of pads of the first pad group and a plurality of pads of the second pad group are aligned with each other.

8. The array substrate according to claim 1, wherein a plurality of pads of the first pad group and a plurality of pads of the second pad group are staggered with each other.

9. The array substrate according to claim 1, wherein the wiring of the first film layer in the first area is further led out to connect with a test pad.

10. A display device, comprising:
a third substrate;
a first substrate disposed opposite the third substrate;
a flexible circuit substrate connected with the first substrate, and having a first area close to the first substrate, a second area located on one side of the first area away from the first substrate, and a third area located on one side of the second area away from the first area, wherein the flexible circuit substrate comprises:
a second substrate;
a first film layer disposed on the second substrate and forming a plurality of wirings; and
a second film layer disposed under the second substrate and forming a plurality of wirings, wherein a plurality of first via holes in the first area and a plurality of third via holes in the third area are formed between the first film layer and the second film layer;
a first pad group disposed on the first film layer and located in the second area;
a second pad group disposed on the first film layer and located in the second area, and located on one side of the first pad group away from the first substrate;
a source-driving chip disposed on the first film layer and located in the third area, wherein a first output end of the source-driving chip is connected with a pad in the second pad group through the wiring of the first film layer; and
a gate-driving chip disposed on the first film layer and located in the third area, and located on one side of the source-driving chip away from the second pad group, wherein an output end of the gate-driving chip is connected with the wiring of the second film layer through the wiring of the first film layer and the third via hole, and the wiring of the second film layer is connected with a pad of the first pad group through the first via hole and the wiring of the first film layer.

11. The display device according to claim 10, wherein the flexible circuit substrate further has a fourth area located between the second area and the third area, and a plurality of fourth via holes in the fourth area are further formed between the first film layer and the second film layer, wherein a second output end of the source-driving chip is connected with the wiring of the second film layer through the wiring of the first film layer and the fourth via hole, and the wiring of the second film layer is connected with a pad of the first pad group through the first via hole and the wiring of the first film layer.

12. The display device according to claim 11, wherein the first film layer forms a plurality of first upper wirings, a plurality of third upper wirings, and a plurality of fourth upper wirings in the first area, the third area, and the fourth area, respectively, wherein the output end of the gate-driving chip is connected with the wiring of the second film layer through third upper wiring and the third via hole, and the wiring of the second film layer is connected with the pad of the first pad group through the first via hole and the first upper wiring.

13. The display device according to claim 12, wherein the first output end of the source-driving chip is directly connected with the pad of the second pad group through the fourth upper wiring.

14. The display device according to claim 12, wherein the second output end of the source-driving chip is connected with the wiring of the second film layer through the fourth upper wiring and the fourth via hole, and the wiring of the second film layer is connected with the pad of the first pad group through the first via hole and the first upper wiring.

15. The display device according to claim 11, wherein a number of the first output ends is greater than a number of the second output ends.

16. The display device according to claim 10, wherein a plurality of pads of the first pad group and a plurality of pads of the second pad group are aligned with each other.

17. The display device according to claim 10, wherein a plurality of pads of the first pad group and a plurality of pads of the second pad group are staggered with each other.

18. The display device according to claim 10, wherein the wiring of the first film layer in the first area is further led out to connect with a test pad.

19. The display device according to claim 10, wherein a liquid crystal layer or an organic light-emitting layer is further disposed between the first substrate and the third substrate.

20. The display device according to claim 19, wherein on the condition that the liquid crystal layer is disposed between the first substrate and the third substrate, the third substrate is a color filter substrate; on the condition that the organic light-emitting layer is disposed between the first substrate and the third substrate, the third substrate is a protective substrate.
